(19) United States
(12) Patent Application Publication
(10) Pub. No.: US 2022/0416139 A1
(43) Pub. Date: Dec. 29, 2022

(54) ULTRAVIOLET LIGHT-EMITTING DEVICE

(71) Applicant: XIAMEN SAN'AN OPTOELECTRONICS CO., LTD., Xiamen (CN)

(72) Inventors: Bin JIANG, Xiamen (CN); Su-Hui LIN, Xiamen (CN); Min HUANG, Xiamen (CN); Kang-Wei PENG, Xiamen (CN); Ming-Chun TSENG, Xiamen (CN); Wei-Chun TSENG, Xiamen (CN)

(21) Appl. No.: 17/807,922

(22) Filed: Jun. 21, 2022

(30) Foreign Application Priority Data
Jun. 26, 2021 (CN) 202110727159.3

(51) Int. Cl. H01L 33/62; H01L 33/38; H01L 33/20

(52) U.S. Cl. CPC H01L 33/62; H01L 33/382; H01L 33/20

(57) ABSTRACT

An ultraviolet light-emitting device includes a substrate including surface portions, a light-emitting structure including first and second semiconductor layers and an active layer, a first metallic contact electrode, and a second metallic contact electrode. The first and second metallic contact electrodes disposed on the light-emitting structure are respectively electrically connected to the first and second semiconductor layers. The first metallic contact electrode has at least one outer electrode section positioned between the active layer and a laser-cut surface portion. The active layer and the laser-cut surface portion are spaced apart by a minimum distance ranging from 30 μm to 100 μm.

### CROSS-REFERENCE TO RELATED APPLICATION

This application claims priority of Chinese Invention Patent Application No. 202110727159.3, filed on Jun. 26, 2021.

### FIELD

The present disclosure relates to a semiconductor device, and more particularly to an ultraviolet light-emitting device and a light-emitting apparatus including the same.

### BACKGROUND

In recent years, widespread application of ultraviolet light-emitting device (LED), in particular deep ultraviolet LED, has attracted great attention and become a new research focus. In order to increase light emission efficiency of an ultraviolet LED, a thick sapphire substrate would be required for improving light extraction.

A method for manufacturing the LED includes a step of performing a stealth laser cutting process, in which inner portions of a substrate formed with crack spots are cut using laser (particularly infrared laser having a wavelength of greater than 600 nm) so as to obtain a plurality of LED chips. An increase in thickness of a substrate would require a stealth laser cutting process to be performed with increased power, and increased number of times, resulting in an epitaxial active layer of the LED being prone to damage.

### SUMMARY

Therefore, an object of the present disclosure is to provide an ultraviolet light-emitting device that can alleviate at least one of the drawbacks of the prior art.

According to the present disclosure, the ultraviolet light-emitting device includes a substrate, a light-emitting structure, a first metallic contact electrode, and a second metallic contact electrode. The substrate includes a top surface, a bottom surface that is opposite to the top surface and is for light emission, and a surrounding surface that interconnects the top surface to the bottom surface and that includes a plurality of surface portions. The light-emitting structure includes a first semiconductor layer that is disposed on the top surface of the substrate, and an active layer and a second semiconductor layer that are disposed on the first semiconductor layer in such order. The first metallic contact electrode and the second metallic contact electrode are disposed on the light-emitting structure opposite to the substrate, and are electrically connected to the first semiconductor layer and the second semiconductor layer, respectively. At least one of the surface portions of the surrounding surface of the substrate is laser cut. The substrate has a thickness ranging from 300 μm to 900 μm. The first metallic contact electrode has at least one outer electrode section that is positioned between the active layer and the surface portion which is laser cut. The active layer and the surface portion which is laser cut are spaced apart by a minimum distance (D) ranging from 30 μm to 100 μm.

### BRIEF DESCRIPTION OF THE DRAWINGS

Other features and advantages of the present disclosure will become apparent in the following detailed description of the embodiments with reference to the accompanying drawings, of which:

FIG. 1 is a perspective schematic view illustrating a first embodiment of an ultraviolet light-emitting device according to the present disclosure;

FIG. 2 is a top schematic view illustrating the first embodiment of the ultraviolet light-emitting device;

FIG. 3 is a schematic view illustrating a second laser-cut surface portion of a surrounding surface of a substrate of the first embodiment of the ultraviolet light-emitting device;

FIG. 4 is a schematic view illustrating a first laser-cut surface portion of the surrounding surface of the substrate of the first embodiment of the ultraviolet light-emitting device;

FIG. 5 is a schematic view illustrating an oblique lateral side of the surrounding surface of the substrate of the first embodiment of the ultraviolet light-emitting device;

FIG. 6 is a top schematic view illustrating a second embodiment of the ultraviolet light-emitting device;

FIG. 7 is a schematic cross-sectional view taken along line A-A′ of FIG. 6;

FIG. 8 is a top schematic view illustrating a third embodiment of the ultraviolet light-emitting device;

FIG. 9 is a top schematic view illustrating a fourth embodiment of the ultraviolet light-emitting device;

FIG. 10 is a schematic cross-sectional view taken along line B-B′ of FIG. 9;

FIG. 11 is a top schematic view illustrating a fifth embodiment of the ultraviolet light-emitting device;

FIG. 12 is a schematic cross-sectional view illustrating an embodiment of a light-emitting apparatus including the ultraviolet light-emitting device according to the present disclosure; and

FIG. 13 is a schematic cross-sectional view illustrating a variation of the embodiment of the light-emitting apparatus shown in FIG. 12.

### DETAILED DESCRIPTION

Before the present invention is described in greater detail, it should be noted that where considered appropriate, reference numerals or terminal portions of reference numerals have been repeated among the figures to indicate corresponding or analogous elements, which may optionally have similar characteristics.

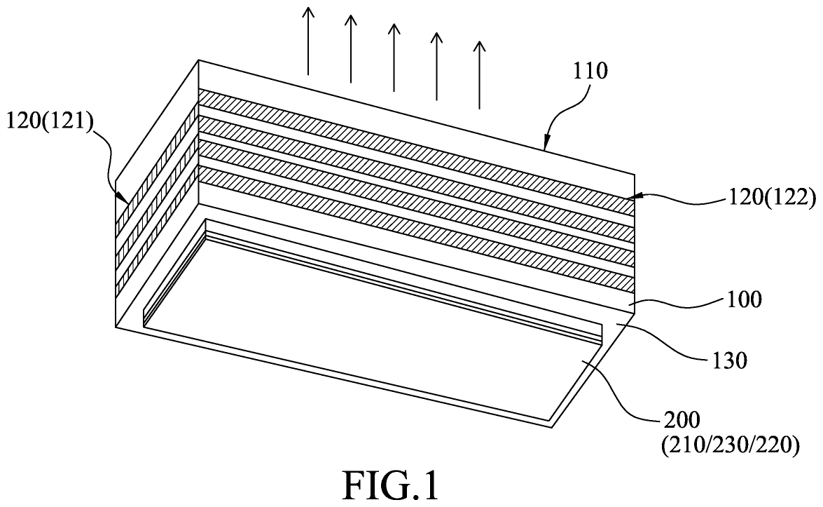

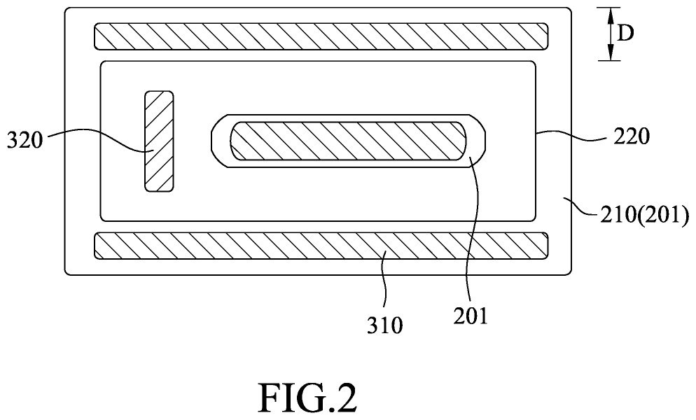

Referring to FIGS. 1 and 2, a first embodiment of an ultraviolet light-emitting device (LED) according to the present disclosure includes a substrate 100, a light-emitting structure 200, a first metallic contact electrode 310, and a second metallic contact electrode 320. The ultraviolet light-emitting device is configured to emit a light having a wavelength ranging from 210 nm to 340 nm.

The substrate 100 has a top surface 130, a bottom surface 110 that is opposite to the top surface 130, and a surrounding surface 120 that interconnects the top surface 130 to the bottom surface 110 and that includes a plurality of surface portions 121, 122.

The substrate 100 may be made of a light-transmissive material. Examples of the light-transmissive material may include, but not limited to, sapphire, glass, and silicon carbide. In the first embodiment, the substrate 100 is made of sapphire. In some embodiments, the substrate 100 may be a transparent substrate obtained after substrate peeling and transfer. In comparison to a conventional gallium nitride (GaN)-based LED having a thickness of about 100 μm, the substrate 100 has a thickness ranging from 300 μm to 900 μm, so as to enhance light extraction efficiency of the ultraviolet LED through the bottom surface 110 of the substrate 100 serving as the light-emitting surface (the direction of light emission from the bottom surface 110 is shown as solid arrows in FIG. 1)

It should be noted that, at least one of the surface portions 121, 122 of the surrounding surface 120 of the substrate 100 is laser cut (see the dashed arrows in FIG. 1). At least one of the top and bottom surfaces 110, 130 of the substrate 100 is rectangular, and has a length in a longitudinal direction and a width in a direction perpendicular to the longitudinal direction. For the substrate 100 having the top and bottom surfaces 130, 110 being rectangular shape, the surrounding surface 120 has four surface portions 121, 122 which are laser cut.

Referring to FIGS. 1, 3 and 4, in the first embodiment, two of the surface portions 121, 122 of the surrounding surface 120 of the substrate 100 are formed adjacent to each other, and are subjected to the laser cutting process so as to form first and second laser-cut surface portions 121, 122 having a plurality of crack spots 123. Due to the crystalline phase of the sapphire substrate 100, the first laser-cut surface portion 122 has a crack spot number greater than that of the second laser-cut surface portion 121. The crack spots 123 of the first laser-cut surface portion 122 are formed in scribe lines 124 to be interconnected, while the crack spots 123 of the second laser-cut surface portion 121 are separated.

It should be noted that, in this embodiment, the first second laser-cut surface portion 122 is formed on the surrounding surface 120 along the length of the top surface 130 in a longitudinal direction, while the second laser-cut surface portion 121 is formed on the surrounding surface 120 along the width of the top surface 130 in a direction perpendicular to the longitudinal direction. In other embodiments, the first and second laser-cut surface portions 122, 121 are formed on the surrounding surface 120 along the length of the top surface 130 in the longitudinal direction and the direction perpendicular to the longitudinal direction, respectively. During a manufacturing process of the ultraviolet LED, the laser cutting process for each of the surface portions 121, 122 may be performed using the same or different cutting conditions, such as number of cuts (i.e., the number of focal points on the laser-cut surface portions 121, 122), cutting speed, and power. In this embodiment, the laser cutting process is a stealth laser cutting process.

The light-emitting structure 200 includes a first semiconductor layer 210 that is disposed on the top surface 130 of the substrate 100, and an active layer 230 and a second semiconductor layer 220 that are disposed on the first semiconductor layer 210 in such order. The first semiconductor layer 210 may be an N-type layer, and the second semiconductor layer 220 may be a P-type layer, or vice versa. The active layer 230 includes aluminum in an amount of 30% based on a total weight of the active layer 230. In this embodiment, the light-emitting structure 200 is made by chemical vapor deposition.

The light-emitting structure 200 has a plurality of recess portions 201 formed by partially removing the second semiconductor layer 220 and the active layer 230 such that at least one portion of the first semiconductor layer 210 is exposed from the recess portions 201 (see FIG. 2).

The first and second metallic contact electrode 310, 320 are disposed on the light-emitting structure 200 opposite to the substrate 100. The first metallic contact electrode 310 is electrically connected to the first semiconductor layer 210, and has at least one outer electrode section and at least one inner electrode section, both of which are disposed in the recess portions 201. Alternatively, the at least one outer electrode section of the first metallic contact electrode 310 may be directly disposed on a peripheral region of the first semiconductor layer 210, or indirectly disposed thereon through an intermediate layer, such as a current blocking layer formed with an opening, or a transparent conductive layer. The second metallic contact electrode 320 is electrically connected to the second semiconductor layer 220, and may be directly disposed on the second semiconductor layer 220, or indirectly disposed thereon through the intermediate layer. In this embodiment, one of the first metallic contact electrode 310 and the second metallic contact electrode 320 is made of a metal selected from the group consisting of chromium, aluminium, titanium, platinum, gold, or silver.

It should be noted that, the at least one outer electrode section of the first metallic contact electrode 310 is positioned between the surface portion 122 which is laser cut and the active layer 230, so that a distance between the laser-cut surface portion 122 and the active layer 230 along a direction perpendicular to the top surface 130 of the substrate 100 is increased, i.e., increasing the distance between the active layer 230 and the positions of the laser focal points during the laser cutting process. The closer the distance between the active layer 230 and the laser focal points (i.e., the laser-cut surface portions 121, 122 formed with the crack spots 123) is, the more likely the active layer 230 would be damaged during the laser cutting process. Therefore, effective protection for the active layer 230 is achieved by increasing the distance between the laser-cut surface portion 122 and the active layer 230. Since the path of the laser is relatively vertical, the smaller extent of offset in the lateral direction of the path effectively reduces damages to the active layer 230 during the laser cutting process. In this embodiment, the active layer 230 and the surface portion 122 which is laser cut are spaced apart by a minimum distance D ranging from 30 μm to 100 μm.

Referring again to FIGS. 1 and 2, in this embodiment, the first laser-cut surface portion 122 has top and bottom sides respectively proximate to and distal from the light-emitting structure 200, and the outer electrode section of the first metallic contact electrode 310 is disposed adjacent to the top side of the first laser-cut surface portion 122.

In certain embodiments, at least one of the surface portions of said surrounding surface 120 of said substrate 100 has opposite top and bottom sides respectively proximate to and distal from the light-emitting structure 200, and opposite oblique lateral sides each interconnecting said top and bottom sides. When the at least one of the surface portions is the first laser-cut surface portion 122, and the outer electrode section of the first metallic contact electrode 310 is disposed adjacent to the top side of the first laser-cut surface portion 122.

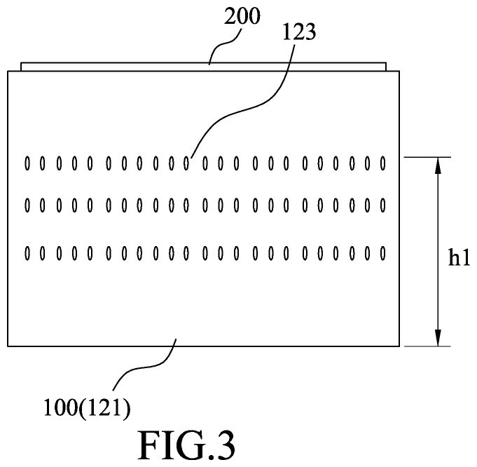

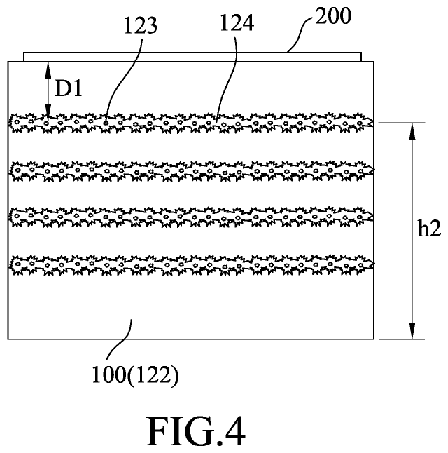

The first laser-cut surface portion 122 is generally affected by the crystalline phase of the substrate 100 and requires the laser cutting process to be performed more vigorously, for example, a higher laser energy or the laser cutting process being directed to more rows of the crack spots 123 that are deeper and closer to the active layer 230 compared to those for the second laser-cut surface portion 121. As shown in FIGS. 3 and 4, in the first embodiment, in order to permit the first laser-cut surface portion 122 to be cut easily, a cut depth (h2) for the first laser-cut surface portion 122 is set to be greater than a cut depth (h1) for the second laser-cut surface portion 121.

In this embodiment, each of the first and second laser-cut surface portions 121, 122 has at least three rows of the crack spots 123, each of which is parallel to the top surface 130 of the substrate 100. The row of the crack spots 133, which belongs to the first and second laser-cut surface portions 121, 122 and is proximate to a peripheral region of the active layer 230, is spaced apart from the peripheral region of the active layer 230 by a distance (D1) not greater than 150 μm. It should be noted that, the number of cuts for the first laser-cut surface portion 122 may be greater than that for the second laser-cut surface 121.

In certain embodiments, based on the requirements of the back-end-of-line applications, the substrate 100, when at least one of the top and bottom surfaces 130, 110 is rectangular, a ratio of the length in the longitudinal direction to the width in the direction perpendicular to the longitudinal direction, in decimal form, ranges from 2 to 8. When the aforesaid ratio of the length to the width of the substrate 100 is too great, the requirements for performing the laser cutting process along the length in the longitudinal direction will be significantly more stringent than those along the width in the direction perpendicular to the longitudinal direction, for example, the need to increase the laser power, the number of cuts, and the depth of cuts along the length of the substrate in the longitudinal direction, or lowering the laser cutting speed. Therefore, in this embodiment, the outer electrode section of the first metallic contact electrode 310 disposed on a peripheral region of the substrate 100 extends in the longitudinal direction to reduce damage caused by the laser cutting process.

In this embodiment, the active layer 230 and the outer electrode section of the first metallic contact electrode 310 each have a length in a longitudinal direction, and the length of the active layer 230 is smaller than that of the outer electrode section of the first metallic contact electrode 310.

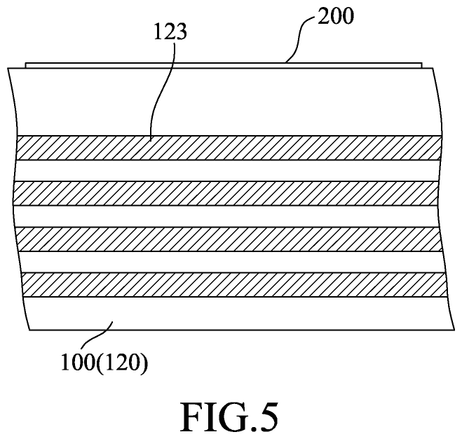

Referring to FIG. 5, in some embodiments, in order to increase the light extraction efficiency of the ultraviolet light-emitting device, in comparison to a conventional substrate having a thickness of about 100 μm, the thickness of the substrate 100 is increased to be greater than 300 μm, which may result in increased difficulty of using the laser cutting process to obtain a plurality of LED chips that are completely separated from each other based on the position of the scribe lines 124 formed by the crack spots 123, and other problems such as the cut lateral surfaces being oblique relative to the top and bottom surfaces 130, 110 of the substrate 100.

Since the substrate 100 includes oblique lateral sides, i.e., the laser-cut surface portions 121, 122 of the surrounding surface 120 which form an approximately parallelogram shape, adjusting the parameters of the laser cutting process, such as increasing the laser power applied to the oblique lateral sides, increasing the number of laser cuts, or lowering the laser cutting speed, may be adopted. Based on adjustments to these parameters, in this embodiment, the outer electrode section of the first metallic contact electrode 310 is disposed on a peripheral region of the oblique lateral sides (FIG. 5 only shows the positional relationship of the light-emitting structure 200 and the laser-cut surface portions of the surrounding surface 120), and the active layer 230 is designed to be distant from the peripheral region of the oblique lateral sides as far as possible, as long as the total area of the active layer 230 is not substantially reduced.

In certain embodiments, when the parameters of laser power and depth of laser cut are independently adjusted in accordance with the lengths of the active layer 230 and the outer electrode section of the first metallic contact electrode 310 in both the longitudinal direction and the direction which is perpendicular to the longitudinal direction, at least some parts of the first metallic contact electrode 310, such as two of the outer electrode sections of the first metallic contact electrode 310, may be disposed in parallel on two sides of the active layer 230. For example, if the first laser-cut surface portions 122 or the oblique lateral sides have lengths in the longitudinal direction, the first metallic contact electrode 310 has two of the outer electrode sections that are disposed in parallel on two sides of the active layer 230.

Alternatively, in the case that the top and bottom surfaces 130, 100 of the substrate 100 are rectangular and have a length in a longitudinal direction, the two of the outer electrode sections of the first metallic contact electrode 310 may be disposed in parallel on two sides of the active layer 230.

In a variation of the first embodiment, when the first laser-cut surface portion 122 of the surrounding surface 120 has a length in a longitudinal direction, the length of the active layer 230 is smaller than that of the outer electrode section of the first metallic contact electrode 310, and the outer electrode section of the first metallic contact electrode 310 is positioned between the active layer 230 and the first laser-cut surface portion 122. In another variation of the first embodiment, when the surrounding surface 120 of the substrate 100 has a width in the direction perpendicular to the longitudinal direction, the outer electrode section of the first metallic contact electrode 310 is positioned between the active layer 230 and the surrounding surface 120 of the substrate 100 along the direction perpendicular to the longitudinal direction. In yet another variation of the first embodiment, when the oblique lateral sides of the substrate 100 has a length along the longitudinal direction, the outer electrode section of the first metallic contact electrode 310 is positioned between the active layer 230 and the oblique lateral sides of the substrate 100.

In certain embodiments, when the length and the width of one of the top and bottom surfaces 130, 110 of the substrate 100 is not greater than 500 μm, the first metallic contact electrode 310 may be completely disposed on the peripheral region of the active layer 230 because the impact of the current spreading problem will be lessened due to the substrate 100 having a relatively smaller size. In order to dispose the first metallic contact electrode 310 on the active layer 230, apart from the size of the substrate 100, an aluminum content in the epitaxial semiconductor layer of the light-emitting structure 200, especially the aluminum content in the N-type layer, should also be taken into consideration because a high content of aluminum will significantly decrease current spreading effect.

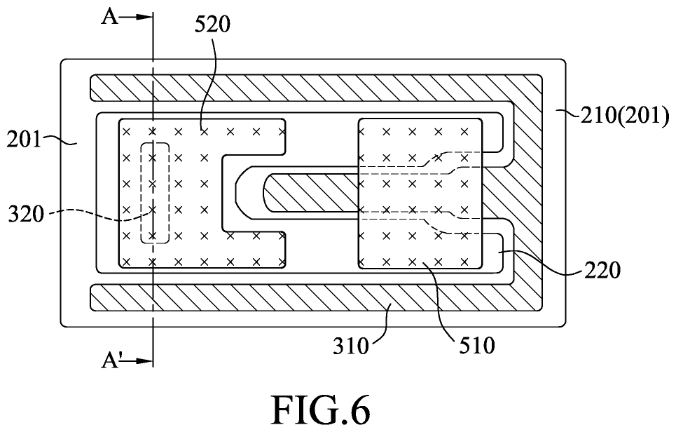

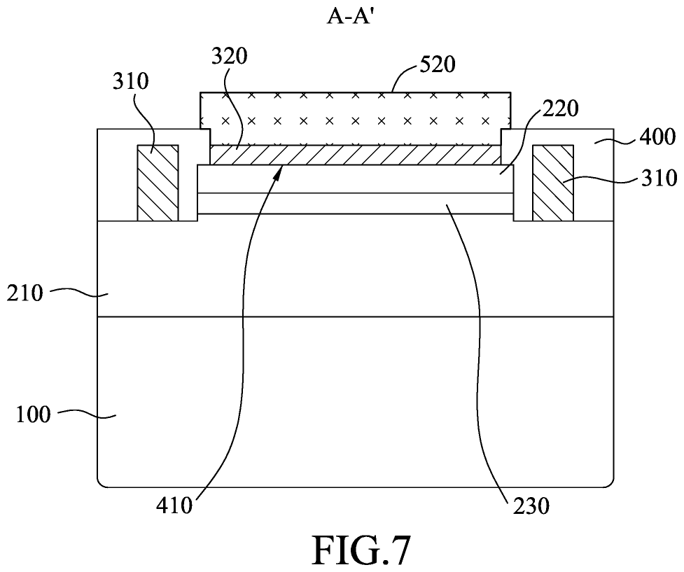

Referring to FIGS. 6 and 7, a second embodiment of the ultraviolet light-emitting device is substantially similar to the first embodiment except for the following differences. In the second embodiment, the length of one of the top and bottom surfaces 130, 110 of the substrate 100 is greater than 500 μm, so that current spreading in the light-emitting structure 200 can be improved. In order to increase current spreading and/or current density in the active layer 230, portions of the second semiconductor layer 220 and the active layer 230 in central and peripheral regions of the light-emitting structure 200 are removed to expose the first semiconductor layer 210 therefrom and to form recess portions 201 that are connected to each other, so as to permit the two outer electrode sections and the inner electrode section of the first metallic contact electrode 310 to be disposed in the recess portions 201. It should be noted that, in this embodiment, the two outer electrode sections and the inner electrode section of the first metallic contact electrode 310 disposed in the recess portions 201 are connected to each other.

Referring again to FIG. 7, the second embodiment of the ultraviolet light-emitting device further includes an insulating layer 400 that covers the first semiconductor layer 210 and the second semiconductor layer 220, a first pad electrode 510 that is disposed on the insulating layer 400 opposite to the first semiconductor layer 210, and a second pad electrode 520 that is disposed on the insulating layer 400 opposite to the second semiconductor layer 220. The insulating layer 400 may be formed with at least one opening 410 to expose at least one of said first metallic contact electrode 310 and said second metallic contact electrode 320. In this embodiment, said second metallic contact electrode 320 is exposed from the opening 410.

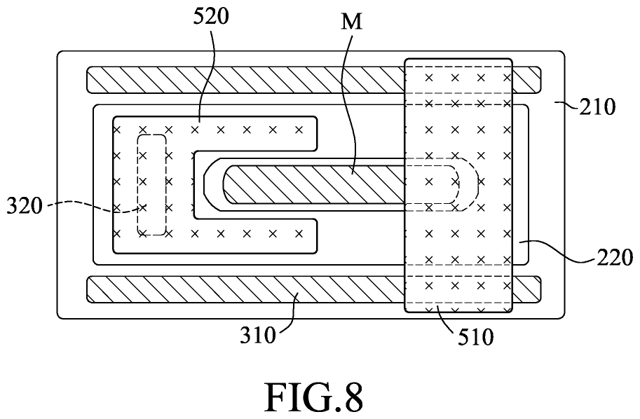

Referring to FIG. 8, a third embodiment of the ultraviolet light-emitting device differs from the second embodiment in that, in order to maximize the light-emitting area of the active layer 230, the inner electrode section of the first metallic contact electrode 310 is disposed in the recess 201 on a central region M of the light-emitting structure 200, while the two outer electrode sections of the first metallic contact electrode 310, each of which is in a continuous form, are separately disposed at the peripheral region of the first semiconductor layer 210 along the two lengths of the top surface 130 of the substrate 100 in the longitudinal direction. The inner electrode section is electrically connected the outer electrode sections via the first pad electrode 510.

In the third embodiment, the insulating layer 400 is formed with first and second openings 410. The first metallic contact electrode 310 is connected to the first pad electrode 510 via the first opening 410, while the second metallic contact electrode 320 is connected to the second pad electrode 520 via the second opening 410.

In this embodiment, the first metallic contact electrode 310 and the first pad electrode 510 are N type, and the second metal contact electrode 320 and the second pad electrode 520 are P type. In order to avoid N-type conductive material and P-type conductive material overlapping with each other, the N-type pad electrode is designed to avoid the P-type electrode, and the P-type pad electrode is designed to avoid the N-type electrode in a manner that, when viewed from top on a projection plane along a vertical direction perpendicular to the top surface 130 of the substrate 100, the P-type electrode does not overlap with the N-type pad, and the N-type electrode does not overlap with the P-type pad.

In this embodiment, the inner electrode section of the first metallic contact electrode 310 has an elongated shape, and when a ratio of the length of the inner electrode section in the central region M of the light-emitting structure 200 to the length of the outer electrode section in the peripheral region of the first semiconductor layer 210 is relatively high, an excellent current spreading in the light-emitting structure 200 can be achieved, thereby increasing photoelectric efficiency of the ultraviolet light-emitting device.

To be specific, when the top surface 130 of the substrate 100 is rectangular and the length in the longitudinal direction is different from the width in the direction perpendicular to the longitudinal direction, the first and second pad electrodes 510, 520 are respectively disposed on the insulating layer 400 along the two lengths of the top surface 130 of the substrate 100 in the longitudinal direction. In a top view of the projection plane along the vertical direction perpendicular to the top surface 130 of the substrate 100, the second pad electrode 520 (i.e., a P-type pad electrode) is U-shaped, and faces the first pad electrode 510 (i.e., an N-type pad electrode). The inner electrode section of the first metallic contact electrode 310 (i.e., an N-type contact electrode) is disposed in the recess portion 201 on the central region M of the light-emitting structure 200, and two outer electrode sections of the first metallic contact electrode 310 are respectively disposed in parallel on two sides of the active layer 230 along the two lengths of the top surface 130 of the substrate 100 in the longitudinal direction. The inner electrode section of the first metallic contact electrode 310 extends underneath from the first pad electrode 510 to face the U-shaped second pad electrode 520.

As shown in FIG. 8, in the third embodiment, the two arms of the U-shaped second pad electrode 520 are formed parallel to each other, and surround a part of the inner electrode section of the first metallic contact electrode 310. In addition, a length of the first pad electrode 510 along the length of the top surface 130 of the substrate 100 in the longitudinal direction is less than that of the second pad electrode 520, while a width of the first pad electrode 510 along the width of the top surface 130 of the substrate 100 in the direction perpendicular to the longitudinal direction is greater than that of the second pad electrode 520. Moreover, in the top view of the projection plane along the vertical direction perpendicular to the top surface 130 of the substrate 100, a ratio of an area of the first pad electrode 510 to an area of the second pad electrode 520 in decimal form ranges from 0.8 to 1.2.

As mentioned above, in the top view of the projection plane along the vertical direction perpendicular to the top surface 130 of the substrate 100, since the first metallic contract electrode 310 does not overlap with the second pad electrode 520, and the second metallic contact electrode 320 does not overlap with the first pad electrode 510, the risk of short circuit due to cracking or abnormalities of the insulation layer 400 positioned between the first and second metallic contact electrodes 310, 320 and the first and second pad electrodes 510, 520 is reduced.

In order to achieve the effect of die bonding, the P-type pad electrode (i.e., the second pad electrode 520) should have a sufficiently large surface area. That is, the surface area of the P-type pad electrode be similar to that of the N-type pad electrode (i.e., the first pad electrode 510) so that the LED chip is sufficiently bonded during packaging process, thereby enhancing the reliability of the ultraviolet light-emitting device. In this embodiment, since the length of the first pad electrode 510 along the length of the top surface 130 of the substrate 100 in the longitudinal direction is less than that of the second pad electrode 520, the width of the first pad electrode 510 along the width of the top surface 130 of the substrate 100 in the direction perpendicular to the longitudinal direction is increased to be greater than that of the second pad electrode 520.

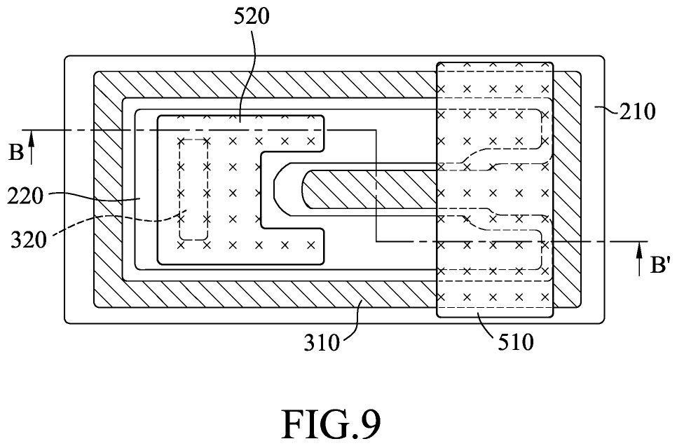

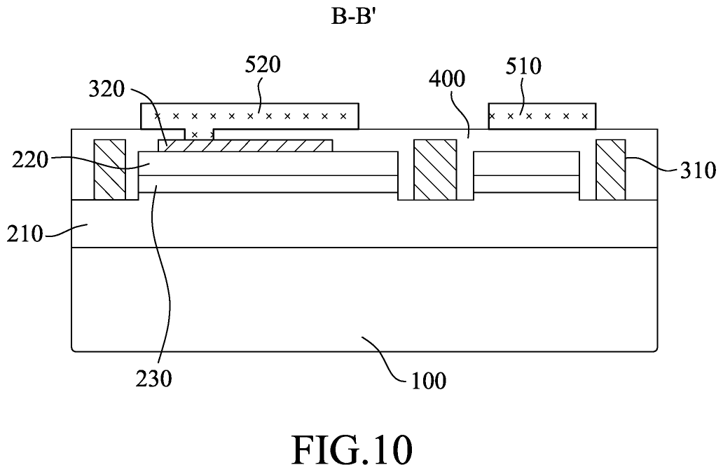

Referring to FIGS. 9 and 10, a fourth embodiment of the ultraviolet light-emitting device of the present disclosure is substantially similar to the third embodiment except that, in the fourth embodiment, the recess portions 201 interconnecting with each other are formed in the central region M of the light-emitting structure 200 and along the entire peripheral region thereof (i.e., along the two lengths of the top surface 130 of the substrate 100 in the longitudinal direction and the two widths of the top surface 130 of the substrate 100 in the direction perpendicular to the longitudinal direction), such that the first metallic contact electrode 310 (including the inner and outer electrode sections) disposed in the recess portions 201 surrounds the active layer 230, thereby protecting the active layer 230 from being damaged during the laser cutting process.

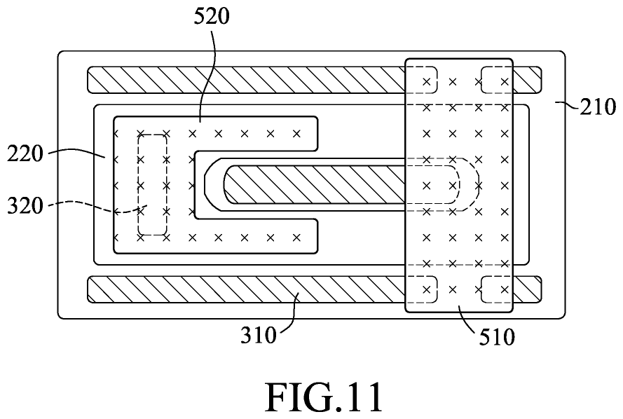

Referring to FIG. 11, a fifth embodiment of the ultraviolet light-emitting device of present disclosure is substantially similar to the third embodiment except that, in the fifth embodiment, the two outer electrode sections of the first metallic contact electrode 310 disposed in parallel along the two lengths of the top surface 130 of the substrate 100 in the longitudinal direction are in a non-continuous form. Specifically, in this embodiment, each of the outer electrode sections is separated into two outer electrode portions having different lengths in the longitudinal direction, and the length of the two outer electrode portions in the longitudinal direction may be adjusted according to practical requirements, such as uniformity of current spreading. As shown in FIG. 11, the four outer electrode portions are electrically connected to each other by the first pad electrode 510. In the fifth embodiment, two of the outer electrode portions which are proximate to the second pad electrode 520 each has a length greater than the length of the other two outer electrode portions which are proximate to the first pad electrode 510.

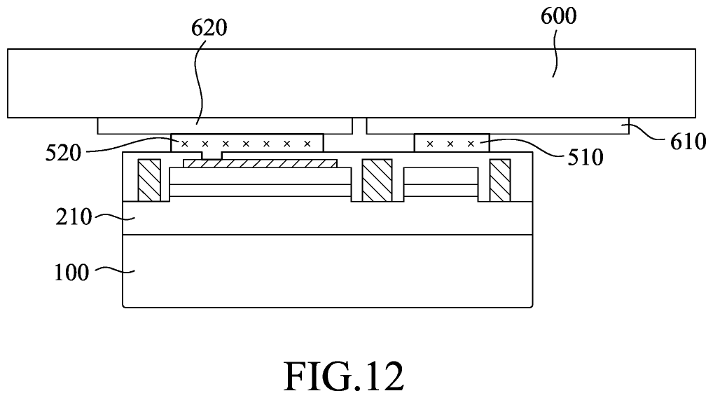

FIG. 12 illustrates an embodiment of a light-emitting apparatus including one of the aforementioned third to the fifth embodiments of the ultraviolet light-emitting devices. In this embodiment, the ultraviolet light-emitting device is connected to a circuit board 600 through a first conductive layer 610 and a second conductive layer 620 which are spaced apart from each other. To be specific, the first pad electrode 510 is electrically connected to the circuit board 600 through the first conductive layer 610, and the second pad electrode 520 is electrically connected to the circuit board 600 through the second conductive layer 620.

In this embodiment, the size areas of the first and the second pad electrode 510, 520 are substantially similar, for example, the ratio of the area of the first pad electrode 510 to the area of the second pad electrode 520 in decimal form ranges from 0.8 to 1.2, thus, the light-emitting apparatus, regardless of including the third, fourth or fifth embodiment of the ultraviolet light-emitting device, when manufactured under the same conditions, will show an improved die-bonding and reliability compared to a conventional ultraviolet light-emitting device.

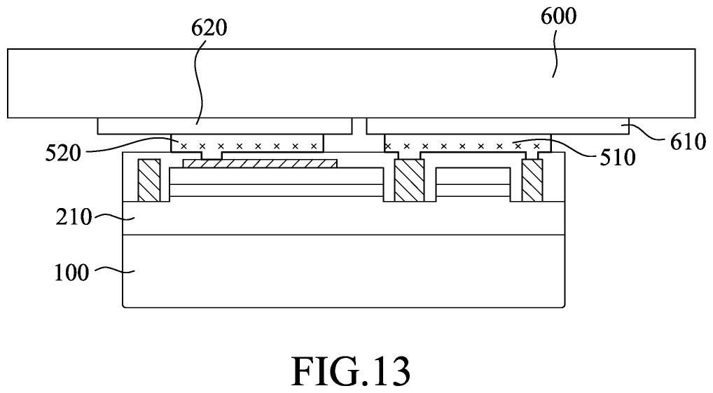

FIG. 13 illustrates a variation of the embodiment of the light emitting apparatus shown in FIG. 12. This variation is substantially similar to the embodiment shown in FIG. 12, except that some of the outer electrode sections of the first metallic contact electrode 310 are respectively exposed from the openings 410 formed on the insulating layer 400 to be electrically connected to the first pad electrode 510.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. An ultraviolet light-emitting device, comprising:
a substrate having a top surface, a bottom surface that is opposite to said top surface and is for light emission, and a surrounding surface that interconnects said top surface to said bottom surface and that includes a plurality of surface portions;
a light-emitting structure including a first semiconductor layer that is disposed on said top surface of said substrate, and an active layer and a second semiconductor layer that are disposed on said first semiconductor layer in such order; and
a first metallic contact electrode and a second metallic contact electrode that are disposed on said light-emitting structure opposite to said substrate, and that are electrically connected to said first semiconductor layer and said second semiconductor layer, respectively,
wherein at least one of said surface portions of said surrounding surface of said substrate is laser cut, said substrate having a thickness ranging from 300 μm to 900 μm,
wherein said first metallic contact electrode has at least one outer electrode section that is positioned between said active layer and said surface portion which is laser cut, and
wherein said active layer and said surface portion which is laser cut are spaced apart by a minimum distance ranging from 30 μm to 100 μm.

2. The ultraviolet light-emitting device as claimed in claim 1, wherein said first metallic contact electrode surrounds said active layer.

3. The ultraviolet light-emitting device as claimed in claim 1, wherein said first metallic contact electrode is in one of a continuous form and a non-continuous form.

4. The ultraviolet light-emitting device as claimed in claim 1, wherein said outer electrode section of said first metallic contact electrode is disposed on a peripheral region of said first semiconductor layer.

5. The ultraviolet light-emitting device as claimed in claim 1, wherein two of said surface portions of said surrounding surface of said substrate are formed adjacent to each other and are subjected to a laser cutting process to form first and second laser-cut surface portions having a plurality of crack spots, said first laser-cut surface portion having a crack spot number greater than that of said second laser-cut surface portion, said crack spots of said first laser-cut surface portion being formed in scribe lines to be interconnected, said crack spots of said second laser-cut surface portion being separated, said first laser-cut surface portion having top and bottom sides respectively proximate to and distal from said light-emitting structure, said outer electrode section of said first metallic contact electrode being disposed adjacent to said top side of said first laser-cut surface portion.

6. The ultraviolet light-emitting device as claimed in claim 1, wherein at least one of said surface portions of said surrounding surface of said substrate has opposite top and bottom sides respectively proximate to and distal from said light-emitting structure, and opposite oblique lateral sides each interconnecting said top and bottom sides, and said outer electrode section of said first metallic contact electrode is disposed adjacent to said top side of said surface portion.

7. The ultraviolet light-emitting diode as claimed in claim 1, wherein said active layer and said outer electrode section of said first metallic contact electrode each have a length in a longitudinal direction, said length of said active layer being smaller than that of said outer electrode section of said first metallic contact electrode.

8. The ultraviolet light-emitting device as claimed in claim 1, wherein said first metallic contact electrode has two of said outer electrode sections that are disposed in parallel on two sides of said active layer.

9. The ultraviolet light-emitting device as claimed in claim 5, wherein each of said first and second laser-cut surface portions has at least three rows of said crack spots, each of which is parallel to said top surface of said substrate, said row of said crack spots, which belongs to said first and second laser-cut surface portions and is proximate to a peripheral region of said active layer, being spaced apart from said peripheral region of said active layer by a distance not greater than 150 μm.

10. The ultraviolet light-emitting device as claimed in claim 1, wherein at least one of said top and bottom surfaces of said substrate is rectangular and has a length in a longitudinal direction and a width in a direction perpendicular to the longitudinal direction, a ratio of said length to said width in decimal form ranging from 2 to 8.

11. The ultraviolet light-emitting diode as claimed in claim 10, wherein said outer electrode section of said first metallic contact electrode extends in the longitudinal direction.

12. The ultraviolet light-emitting device as claimed in claim 1, which is configured to emit a light having a wavelength ranging from 210 nm to 340 nm.

13. The ultraviolet light-emitting device as claimed in claim 1, further comprising an insulating layer that covers said first semiconductor layer and said second semiconductor layer, a first pad electrode that is disposed on said insulating layer opposite to said first semiconductor layer, and a second pad electrode that is disposed on said insulating layer opposite to said second semiconductor layer.

14. The ultraviolet light-emitting device as claimed in claim 13, wherein said insulating layer is formed with at least one opening to expose at least one of said first metallic contact electrode and said second metallic contact electrode.
